(19) United States
(12) Patent Application Publication
(10) Pub. No.: US 2024/0120183 A1
(43) Pub. Date: Apr. 11, 2024

(54) SUBSTRATE PROCESSING METHOD AND SUBSTRATE PROCESSING APPARATUS

(71) Applicant: Tokyo Electron Limited, Minato-ku, Tokyo (JP)

(72) Inventors: Makoto WADA, Nirasaki-shi, Yamanashi (JP); Ryota IFUKU, Nirasaki-shi, Yamanashi (JP); Takashi MATSUMOTO, Nirasaki-shi, Yamanashi (JP); Hiroki YAMADA, Nirasaki-shi, Yamanashi (JP)

(21) Appl. No.: 18/263,920

(22) PCT Filed: Jan. 24, 2022
(86) PCT No.: PCT/JP2022/002309

§ 371 Date: Aug. 2, 2023

(30) Foreign Application Priority Data
Feb. 5, 2021 (JP) 2021-017751

(51) Int. Cl. H01J 37/32; C23C 16/26; C23C 16/455; C23C 16/511; C23C 16/52; H01L 21/02

(52) U.S. Cl. CPC H01J 37/32816; C23C 16/26; C23C 16/45557; C23C 16/511; C23C 16/52; H01J 37/32743; H01L 21/02115; H01L 21/02274; H01J 37/32192; H01J 2237/182; H01J 2237/332

(57) ABSTRACT

A substrate processing method of processing a substrate includes: a carry-in process of carrying the substrate into a processing container; a first process of forming a first carbon film on the substrate with plasma of a first mixture gas containing a carbon-containing gas in a state in which interior of the processing container is maintained at a first pressure; and a second process of changing a pressure in the processing container to a second pressure higher than the first pressure.

### TECHNICAL FIELD

The present disclosure relates to a substrate processing method and a substrate processing apparatus.

### BACKGROUND

In recent years, graphene films have been proposed as new thin-film barrier layer materials to replace metal nitride films. A graphene film forming technique has proposed to directly form a graphene film on a silicon substrate, an insulating film, or the like by forming the graphene film at a high radical density and a low electron temperature by using, for example, a microwave plasma chemical vapor deposition (CVD) apparatus (see, e.g., Patent Document 1). In the graphene film formation, amorphous carbon or the like is formed on an inner wall, such as the side wall, lid, and ceiling plate of a chamber, which have a temperature lower than the temperature of the stage. Removal of a carbon-containing film such as amorphous carbon deposited on the inner wall of the chamber is normally performed because the carbon-containing film causes particles and the like. For example, it has been proposed to clean the interior of the chamber with a cleaning gas before film formation and to pre-coat a film that does not easily react with a film forming gas, thereby suppressing the generation of particles (see, for example, Patent Document 2).

### PRIOR ART DOCUMENTS

### Patent Documents

Patent Document 1: Japanese Patent Laid-open Publication No. 2019-055887
Patent Document 2: Japanese Patent Laid-open Publication No. 10-144667

The present disclosure provides a substrate processing method and substrate processing apparatus capable of reducing particle generation.

### SUMMARY

A substrate processing method according to an embodiment of the present disclosure for processing a substrate includes: a carry-in process of carrying the substrate into a processing container; a first process of forming a first carbon film on the substrate with plasma of a first mixture gas containing a carbon-containing gas in a state in which interior of the processing container is maintained at a first pressure; and a second process of changing a pressure in the processing container to a second pressure which is higher than the first pressure.

According to the present disclosure, generation of particles can be reduced.

### BRIEF DESCRIPTION OF DRAWINGS

FIG. 1 is a view illustrating an example of a substrate processing apparatus according to a first embodiment of the present disclosure.

FIG. 2 is a view schematically illustrating an example of a state of a film forming process in the first embodiment.

FIG. 3 is a view schematically illustrating an example of a state of a pressure change process in the first embodiment.

FIG. 4 is a view schematically illustrating an example of a state from a pressure adjustment process to a carry-out process in the first embodiment.

FIG. 5 is a flowchart illustrating an example of the film forming process in the first embodiment.

FIG. 6 is a view illustrating an example of a comparison of the numbers of particles between Comparative Example and Example 1.

FIG. 7 is a view illustrating an example of a comparison of the numbers of particles between Comparative Example and Example 2.

FIG. 8 is a view illustrating an example of a comparison of the numbers of particles between Comparative Example and Example 3.

FIG. 9 is a view illustrating an example of a substrate processing apparatus according to a second embodiment of the present disclosure.

### DETAILED DESCRIPTION

Embodiments of a substrate processing method and substrate processing apparatus disclosed herein will be described in detail below with reference to the drawings. The technology disclosed herein is not limited by the following embodiments.

An amorphous carbon film formed on an inner wall of a chamber by graphene film formation has a high film forming rate because the temperature of the inner wall of the chamber is low, and thus tends to be plate-shape (flake-shape). When the plate-shape amorphous carbon peels off during or after the graphene film is formed, the amorphous carbon will adhere to a substrate or float, causing particles. Therefore, it is desired to reduce particle generation.

### First Embodiment

### [Configuration of Substrate Processing Apparatus 100]

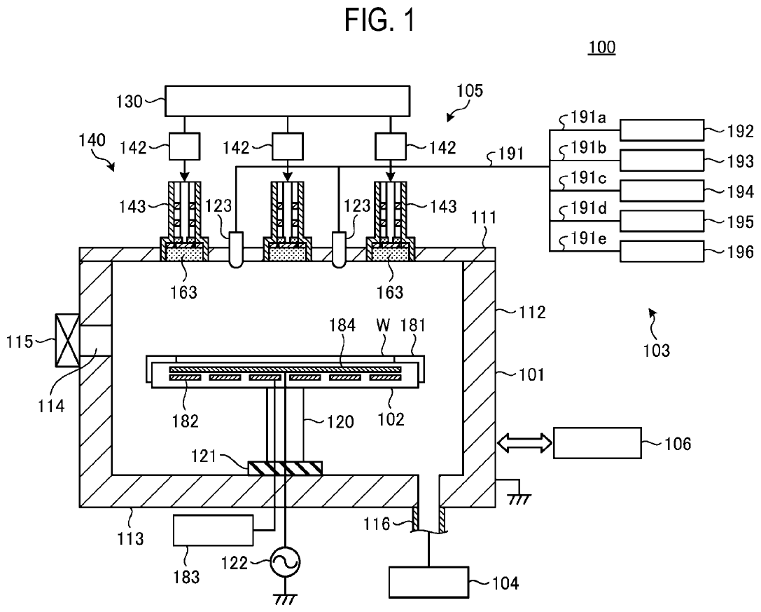

FIG. 1 is a view illustrating an example of a substrate processing apparatus according to a first embodiment of the present disclosure. The substrate processing apparatus 100 illustrated in FIG. 1 includes a processing container 101, a stage 102, a gas supplier 103, an exhauster 104, a microwave introducer 105, and a controller 106. The processing container 101 accommodates a wafer W. The wafer W is placed on the stage 102. The gas supplier 103 supplies gas into the processing container 101. The interior of the processing container 101 is evacuated by the exhauster 104. The microwave introducer 105 generates microwaves for generating plasma in the processing container 101 and introduces the microwaves into the processing container 101. The controller 106 controls the operation of each part of the substrate processing apparatus 100.

The processing container 101 is formed of a metal material, such as aluminum or an alloy thereof, in a substantially cylindrical shape, and has a plate-shaped ceiling wall 111, a bottom wall 113, and a side wall 112 connecting the ceiling wall 111 and the bottom wall 113. The microwave introducer 105 is provided above the processing container 101 and functions as a plasma generator that introduces electromagnetic waves (microwaves) into the processing container 101 to generate plasma. The microwave introducer 105 will be described in detail later.

The ceiling wall 111 has a plurality of openings into each of which a microwave radiation mechanism and a gas introduction portion of the microwave introducer 105 to be described later are fitted. The side wall 112 has a carry-in/out port 114 for performing carry-in/out of a wafer W, which is a substrate to be processed, with respect to a transport chamber (not illustrated) adjacent to the processing container 101. The carry-in/out port 114 is configured to be opened and closed by a gate valve 115. The bottom wall 113 is provided with an exhauster 104. The exhauster 104 is provided in an exhaust pipe 116 connected to the bottom wall 113 and includes a vacuum pump and a pressure control valve. By the vacuum pump of the exhauster 104, the interior of the processing container 101 is evacuated through the exhaust pipe 116. The pressure in the processing container 101 is controlled by the pressure control valve.

The stage 102 has a disk shape and is made of ceramic such as AlN. The stage 102 is supported by a cylindrical support member 120 made of ceramic such as AlN and extending upward from the center of the bottom of the processing container 101 and a base member 121. A guide ring 181 configured to guide the wafer W is provided on the outer edge of the stage 102. In addition, inside the stage 102, lifting pins (not illustrated) configured to raise/lower the wafer W are provided to be capable of protruding/retracting with respect to the top surface of the stage 102.

A resistance heating-type heater 182 is embedded inside the stage 102. The heater 182 heats the wafer W on the stage 102 via the stage 102 by being fed with power from a heater power supply 183. A thermocouple (not illustrated) is inserted into the stage 102, and the stage 102 is configured to be capable of controlling the heating temperature of the wafer W to a predetermined temperature in the range of, for example, 300 to 1,000 degrees C., based on a signal from the thermocouple. In addition, an electrode 184 having a size similar to that of the wafer W is embedded above the heater 182 in the stage 102, and a radio frequency bias power supply 122 is electrically connected to the electrode 184. Radio frequency bias for attracting ions is applied from the radio-frequency bias power supply 122 to the stage 102. The radio frequency bias power supply 122 may not be provided depending on plasma processing characteristic.

The gas supplier 103 is configured to introduce plasma generating gas and a raw material gas for forming a graphene film (a carbon-containing film) into the processing container 101, and has a plurality of gas introduction nozzles 123. The gas introduction nozzles 123 are fitted into respective openings formed in the ceiling wall 111 of the processing container 101. A gas supply pipe 191 is connected to the gas introduction nozzles 123. The gas supply pipe 191 branches into five branch pipes 191a, 191b, 191c, 191d, and 191e. An Ar gas source 192, an O₂ gas source 193, a N₂ gas source 194, a H₂ gas source 195, and a C₂H₂ gas source 196 are connected to these branch pipes 191a, 191b, 191c, 191d, and 191e, respectively. The Ar gas source 192 supplies Ar gas as a rare gas, which is a plasma generating gas. The O₂ gas source 193 supplies O₂ gas as an oxidizing gas, which is a cleaning gas. The N₂ gas source 194 supplies N₂ gas used as a purge gas or the like. The H₂ gas source 195 supplies H₂ gas as a reducing gas. The C₂H₂ gas source 196 supplies acetylene (C₂H₂) gas as a carbon-containing gas, which is a film-forming raw material gas. In addition, the C₂H₂ gas source 196 may supply another carbon-containing gas such as ethylene (C₂H₄).

Although not illustrated, each of the branch pipes 191a, 191b, 191c, 191d, and 191e is provided with a mass flow controller for controlling a flow rate and valves before and after the mass flow controller. Alternatively, a shower plate may be provided to supply C₂H₂ gas and H₂ gas to a position near the wafer W to adjust gas dissociation. The same effect can also be obtained by extending nozzles for supplying these gases downward.

As described above, the microwave introducer 105 is provided above the processing container 101 and functions as a plasma generator that introduces electromagnetic waves (microwaves) into the processing container 101 to generate plasma.

The microwave introducer 105 includes the ceiling wall 111 of the processing container 101, a microwave output part 130, and an antenna unit 140. The ceiling wall 111 functions as a ceiling plate. The microwave output part 130 generates microwaves and distributes and outputs the microwaves to a plurality of paths. The antenna unit 140 introduces the microwaves output from the microwave output part 130 into the processing container 101.

The microwave output part 130 includes a microwave power supply, a microwave oscillator, an amplifier, and a distributor. The microwave oscillator is solid state and oscillates microwaves at, for example, 860 MHz (e.g., PLL oscillation). The frequency of microwaves is not limited to 860 MHz, and a frequency in the range of 700 MHz to 10 GHz, such as 2.45 GHz, 8.35 GHz, 5.8 GHz, or 1.98 GHz, may be used. The amplifier amplifies the microwaves oscillated by the microwave oscillator. The distributor distributes the microwaves amplified by the amplifier to a plurality of paths. The distributor distributes microwaves while matching the impedance on the input and output sides.

The antenna unit 140 includes a plurality of antenna modules. Each of the antenna modules introduces the microwaves distributed by the distributor of the microwave output part 130 into the processing container 101. The configurations of the plurality of antenna modules are all the same. Each antenna module includes an amplifier 142 configured mainly to amplify and output the distributed microwaves, and a microwave radiation mechanism 143 configured to radiate, into the processing container 101, the microwaves output from the amplifier 142.

The amplifier 142 includes a phase shifter, a variable gain amplifier, a main amplifier, and an isolator. The phase shifter changes the phase of the microwaves. The variable gain amplifier adjusts the power level of the microwaves input to the main amplifier. The main amplifier is configured as a solid state amplifier. The isolator separates reflected microwaves that are reflected by the antennas of the microwave radiation mechanisms 143 (to be described later) and headed toward the main amplifier.

As illustrated in FIG. 1, a plurality of microwave radiation mechanisms 143 are provided on the ceiling wall 111. In addition, the microwave radiation mechanisms 143 each has a cylindrical outer conductor and an inner conductor provided coaxially with the outer conductor within the outer conductor. The microwave radiation mechanisms 143 each has a coaxial tube having a microwave transmission path between the outer conductor and the inner conductor, and an antenna that radiates microwaves into the processing container 101. Microwave transmitting plates 163 fitted in the ceiling wall 111 are provided on the bottom surface side of the antennas, and the bottom surfaces thereof are exposed to the internal space of the processing container 101. The microwaves transmitted through the microwave transmitting plates 163 generate plasma in the space within the processing container 101.

The controller 106 is typically configured with a computer, and controls each part of the substrate processing apparatus 100. The controller 106 includes a storage that stores a process sequence of the substrate processing apparatus 100 and process recipes as control parameters, an input part, and a display, and is able to perform predetermined control according to a selected process recipe.

For example, the controller 106 controls each part of the substrate processing apparatus 100 so as to perform a film-forming method which will be described later. As a detailed example, the controller 106 executes a carry-in process of carrying a substrate (wafer W) into the processing container 101. The controller 106 executes a film forming process of forming a first carbon film on the substrate with plasma of a first mixture gas containing a carbon-containing gas while the interior of the processing container 101 is maintained at a first pressure. Here, as the carbon-containing gas, acetylene (C₂H₂) gas supplied from the C₂H₂ gas source 196 may be used. In addition, the first mixture gas may contain Ar gas supplied from the Ar gas source 192 and H₂ gas supplied from the H₂ gas source 195. The controller 106 executes a pressure change process of changing the pressure in the processing container 101 to a second pressure higher than the first pressure. Here, it is assumed that the first pressure is, for example, 50 mTorr and the second pressure is, for example, 1 Torr.

### [State of Amorphous Carbon Film]

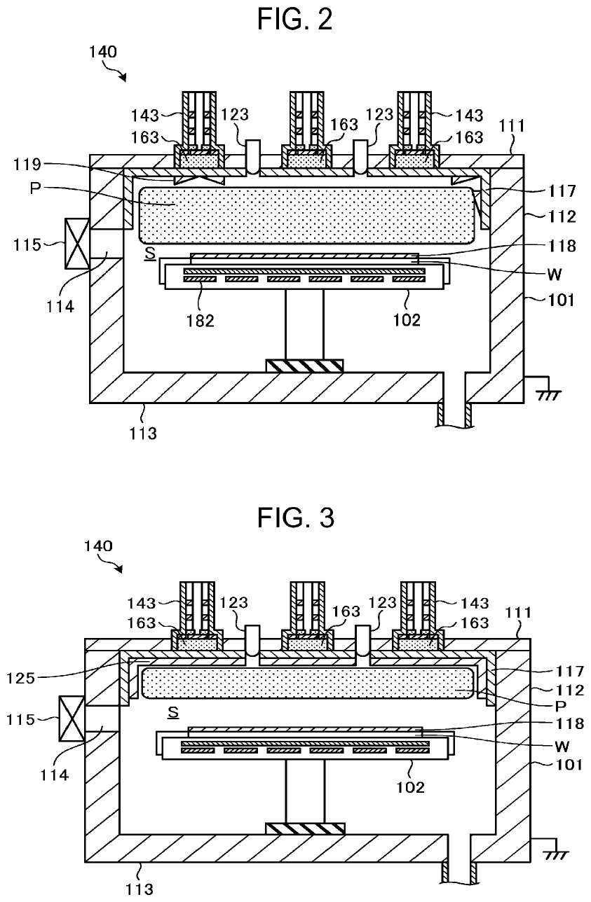

Next, a state of an amorphous carbon film formed on an inner wall of a processing container 101 will be described with reference to FIGS. 2 to 4. In the processing container 101 illustrated in FIGS. 2 to 4, a ceramic thermal spray coating 117, such as a metal oxide (yttria or the like) or a metal nitride, is formed as a surface coating on the inner wall of the ceiling wall 111 and the upper portion of the side wall 112.

FIG. 2 is a view schematically illustrating an example of the state of a film forming process in the first embodiment. As illustrated in FIG. 2, in the film forming process, the pressure in the processing container 101 is reduced to a first pressure (e.g., 50 mTorr to 200 mTorr), a first mixture gas containing a carbon-containing gas as a plasma generating gas is supplied into the processing container 101 from the gas introduction nozzles 123, and plasma is ignited. In addition, the first mixture gas may contain H₂ gas or N₂ gas. In addition, the first mixture gas may contain an inert gas including a rare gas such as Ar gas, as a dilution gas. As illustrated in FIG. 2, in the space S of the processing container 101, plasma P is formed below the microwave transmitting plate 163, which is a plasma source. The plasma P spreads toward the stage 102 side when the pressure inside the processing container 101 is lowered and is narrowed toward the ceiling wall 111 side when the pressure is raised.

In the film forming process, the plasma P of the first mixture gas containing the carbon-containing gas spreads to the vicinity of the wafer W, and a graphene film 118, which is the first carbon film, is formed on the wafer W. The wafer W is placed on the stage 102, and the temperature of the wafer W is controlled by the heater 182 to a temperature for graphene film formation, for example, 400 degrees C. or higher. As the temperature for graphene film formation, for example, a film forming temperature of about 400 degrees C. to 900 degrees C. is used, wherein the higher the temperature, the higher crystallinity the formed graphene has.

On the other hand, in the film forming process, a plate-shape (flake-shape) amorphous carbon film 119 is formed on the inner wall of the processing container 101. In FIG. 2, the amorphous carbon film 119 is illustrated to emphasize that the amorphous carbon film 119 is a plate-shape. The amorphous carbon film 119 is likely to be formed in the vicinity of the ceiling wall 111, the upper portion of the side wall 112, the gas introduction nozzles 123, and the microwave transmitting plates 163 where plasma density is high, and plasma standing wave position. The temperature of the inner wall of the processing container 101 is set to about 100 degrees C. In graphene film formation, when the temperature is low such as about 100 degrees C., the inner wall of the processing container 101 becomes an adsorption member on which a film is easily formed, and the carbon film formed on the adsorption member becomes an amorphous carbon film. In addition, the forming rate of the amorphous carbon film 119 formed on the inner wall of the processing container 101 is faster than the forming rate of the graphene film 118 because the plasma density is high and the amorphous carbon film is easily adsorbed at the low temperature of the inner wall.

FIG. 3 is a view schematically illustrating an example of the state of a pressure change process in the first embodiment. As illustrated in FIG. 3, in the pressure change process, the pressure in the processing container is changed from the first pressure to a second pressure (e.g., 300 mTorr to 2 Torr) while maintaining the plasma P of the first mixture gas. The second pressure is preferably 400 mTorr to 1 Torr, more preferably 1 Torr. At this time, the first mixture gas is continuously supplied into the processing container 101 from the gas introduction nozzles 123. Since the pressure in the processing container 101 rises from the first pressure to the second pressure, the plasma P narrows toward the ceiling wall 111 as illustrated in FIG. 3, so that an amorphous carbon film 125, which is a second carbon film, is formed on the inner wall of the ceiling wall 111 and the upper portion of the side wall 112 of the processing container 101. That is, in the pressure change process, the amorphous carbon film 125 is actively formed on the inner wall of the ceiling wall 111 and the upper portion of the side wall 112. The amorphous carbon film 125 is coated on the entire inner wall of the ceiling wall 111 and the upper portion of the side wall 112 as a continuous film, thereby making it difficult for the amorphous carbon film 119 formed in the film forming process to peel off.

In addition, in the plasma P, Ar ions, H ions, and H radicals are generated in the pressure change process. In the pressure change process, the surface of the graphene film 118 formed on the wafer W is light-etched by the generated Ar ions, H ions, and H radicals. That is, in the pressure change process, particles of amorphous carbon adhered to the graphene film 118 can be removed. For example, when particles of plate-shape amorphous carbon adhere to the graphene film 118 of the wafer W, light etching causes the particles to lift off and be exhausted. In the pressure change process, since the plasma P is narrowed toward the ceiling wall 111, Ar ions, H ions, and H radicals, which spread more easily than hydrocarbons (C₂H₂), will reach the wafer W. In particular, H ions and H radicals having small atomic weights diffuse quickly.

In addition, while the graphene film 118 is formed flat, the adhered particles have a protruding shape. Since the ions and radicals are concentrated on the protruding portions, discontinuously protruding particles are preferentially etched. H ions and H radicals are generated even when C₂H₂ gas is dissociated. However, by causing a hydrogen-containing gas, such as H₂ gas, to be included in the first mixture gas to activate the plasma P and processing the wafer W with activated species (H ions, H radicals, and the like), the particles adhered to the graphene film 118 can be light-etched more actively. In addition, the reason that the plasma P is maintained in the pressure change process is that sometimes particles have a negative charge, so when the plasma P is turned off, the particles may be adsorbed toward the stage 102, which is electrically grounded. That is, by maintaining the plasma P, the particles floating in the space S can be exhausted in the floating state.

In the pressure change process, the removal of particles by light etching of the surface of the graphene film 118 by Ar ions, H ions, and H radicals can be performed even when the supply of the carbon-containing gas is stopped. That is, in the pressure change process, by stopping the supply of the carbon-containing gas in the state in which the plasma of the first mixture gas is maintained, the first mixture gas may be switched to the second mixture gas which does not contain the carbon-containing gas, and the pressure in the processing container 101 may be changed to the second pressure in the state in which the plasma of the second mixture gas is maintained. In addition, in the pressure change process, the microwave output of the microwave introducer 105 may be changed. Furthermore, in the pressure change process, the pressure may be repeatedly changed within a range of 300 mTorr to 1 Torr. Repeated pressure change generates a purge effect, making it easier to remove particles.

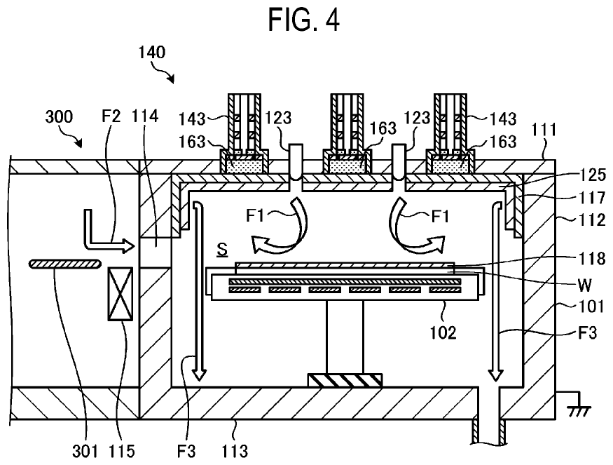

FIG. 4 is a view schematically illustrating an example of the state from a pressure adjustment process to a carry-out process in the first embodiment. FIG. 4 illustrates flows of gases and particles when the pressure adjustment process of making the pressure in the processing container 101 substantially equal to the pressure in the substrate transport chamber 300 and the carry-out process are executed after the pressure change process. The interior of the substrate transport chamber 300 is controlled to have a pressure (e.g., 200 mTorr (26.7 Pa)) higher than a third pressure inside the processing container 101 when the gate valve 115 is opened, i.e., a positive pressure, and in order to prevent particles from being deposited in the substrate transport chamber 300, for example, a bleed gas, such as N₂ gas, is introduced into the substrate transport chamber 300. When the gate valve 115 is opened, a fork 301 of a transport arm is located near the carry-in/out port 114. The reason that the pressure inside the substrate transport chamber 300 is made to have a positive pressure higher than the third pressure in the processing container 101 is to prevent a reactive substance from flowing from the processing container 101 side into the substrate transport chamber 300 side when the gate valve 115 is opened.

However, when the difference between the pressure in the substrate transport chamber 300 and the pressure in the processing container 101 is large when the gate valve 115 is opened, the bleed gas, such as N₂ gas, may flow into the processing container 101 from the substrate transport chamber 300 side, resulting in a large change in gas flow in the processing container 101. Therefore, particles may scatter inside the processing container 101 and may adhere to the wafer W. Therefore, before the gate valve 115 is opened, an inert gas such as Ar gas or N₂ gas is introduced into the processing container 101 in advance to control the pressure inside the processing container 101, so that the pressure difference between the interior of the substrate transport chamber 300 and the interior of the processing container 101 is reduced. In addition, in FIG. 4, the introduction of an inert gas is indicated as flow F1, the flow of a bleed gas from the substrate transport chamber 300 side to the processing container 101 side is indicated as flow F2, and the flow of particles from the amorphous carbon film 125 is indicated as flow F3.

That is, in the pressure adjustment process, the plasma is stopped after the pressure change process, and an inert gas is introduced (flow F1) so that the interior of the processing container 101 becomes the third pressure. The pressure difference between the third pressure and the pressure in the interior of the substrate transport chamber 300 to which the wafer W is carried out is equal to or less than a predetermined value. Here, the predetermined value is, for example, 30 mTorr (4 Pa). In addition, the third pressure is, for example, preferably higher than 100 mTorr and lower than 300 mTorr, more preferably 200 mTorr (26.7 Pa). In addition, as described above, the third pressure is lower than the pressure in the substrate transport chamber 300. That is, the pressure in the processing container 101 is adjusted so that the pressure in the substrate transport chamber 300 becomes positive with respect to that in the processing container 101 when the substrate is transported.

When the pressure in the processing container 101 is adjusted to the third pressure, the gate valve 115 is opened in the state in which the interior of the processing container 101 is maintained at the third pressure. At this time, the bleed gas flows into the processing container 101 from the substrate transport chamber 300 through the carry-in/out port 114 (flow F2). However, since the pressure difference between the substrate transport chamber 300 and the processing container 101 is 30 mTorr or less, the amount of inflow is small. Therefore, even if particles are peeled off from the amorphous carbon film 125, the particles are exhausted as represented by flow F3 so that the particles can be suppressed from adhering onto the wafer W. Thereafter, the wafer W is raised by lifting pins (not illustrated), and the wafer W is carried out from the processing container 101 into the substrate transport chamber 300 by the fork 301. Further, the pressure adjustment process may be performed not only when the wafer W is carried out, but also when the wafer is carried-in.

### [Film Forming Method]

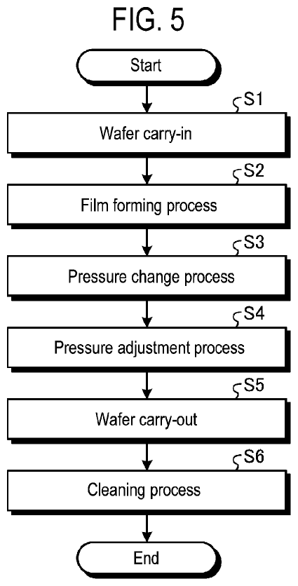

Subsequently, a film forming process according to a first embodiment will be described. FIG. 5 is a flow chart illustrating an example of the film forming process in the first embodiment.

In the film forming process according to the first embodiment, first, the controller 106 controls the gate valve 115 to open the carry-in/out port 114. When the carry-in/out port 114 is opened, a wafer W is carried into the processing space S in the processing container 101 through the carry-in/out port 114 and is placed on the stage 102. That is, the controller 106 carries the wafer W into the processing container 101 (step S1). The controller 106 controls the gate valve 115 to close the carry-in/out port 114.

The controller 106 reduces the pressure in the processing container 101 to a first pressure (e.g., 50 mTorr to 100 mTorr). In addition, the controller 106 controls the temperature of the wafer W to be a predetermined temperature (e.g., 400 degrees C. or higher). The controller 106 supplies a first mixture gas, which is a plasma generating gas, to the processing container 101 from the gas introduction nozzles 123. In addition, the controller 106 causes microwaves, which are distributed and output from the microwave output part 130 of the microwave introducer 105, to be guided into the plurality of antenna modules of the antenna unit 140, and to be radiated from the microwave radiation mechanisms 143 so as to ignite plasma. The controller 106 executes a film forming process with plasma of a first mixture gas for a predetermined time (e.g., 5 seconds to 60 minutes) (step S2). In the film forming process, in order to activate the surface of the wafer W, heat treatment with Ar/H₂ gas or plasma preprocessing with Ar/H₂ gas may be performed as film forming preprocess.

When the film forming process is completed, the controller 106 changes the pressure in the processing container from the first pressure to a second pressure (e.g., 300 mTorr to 2 Torr) while maintaining the plasma of the first mixture gas. The controller 106 executes a pressure change process under the plasma of the first mixture gas for a predetermined time (e.g., 1 second to 60 seconds) (step S2). In addition, the required time of the pressure change process is more preferably 5 seconds. In the pressure change process, an amorphous carbon film 125 is formed on the inner wall of the ceiling wall 111 and the upper portion of the side wall 112, and the surface of a graphene film 118 formed on the wafer W is light-etched by Ar ions, H ions, and H radicals.

When the pressure change process is completed, the controller 106 stops the plasma and executes a pressure adjustment process of changing the pressure in the processing container 101 to a third pressure (e.g., 100 mTorr to 300 mTorr) (step S4). Here, the third pressure is set to a pressure lower than the pressure in the substrate transport chamber 300 by a pressure difference between them of a predetermined value (e.g., 30 mTorr) or less.

When the pressure adjustment process is completed, the controller 106 controls the gate valve 115 to open the carry-in/out port 114 while maintaining the interior of the processing container 101 at the third pressure. The controller 106 raises the wafer W by causing the lifting pins (not illustrated) to protrude from the top surface of the stage 102. The wafer W is carried out from the processing container 101 by a transport arm (not illustrated) of the substrate transport chamber 300 through the carry-in/out port 114 when the carry-in/out port 114 is opened. That is, the controller 106 carries out the wafer W from the interior of the processing container 101 (step S5).

When the wafer W is carried out, the controller 106 executes a cleaning process of cleaning the interior of the processing container 101 (step S6). In the cleaning process, a dummy wafer is placed on the stage 102, a cleaning gas is supplied into the processing container 101 to clean a carbon film such as an amorphous carbon film 125 adhered to the inner wall of the processing container 101. Although O₂ gas may be used as the cleaning gas, the cleaning gas may be an oxygen-containing gas such as CO gas and CO₂ gas. In addition, the cleaning gas may include a rare gas such as Ar gas. The dummy wafer may not be provided. When the cleaning process is completed, the controller 106 ends the film forming process. In this manner, the plate-shape amorphous carbon film 119 adhered to the inner wall of the processing container 101 in the film forming process is covered with an amorphous carbon film 125 in the pressure change process so that the generation of particles can be reduced. In addition, in the pressure change process, since the surface of the wafer W is light-etched by Ar ions, H ions, and H radicals, the particles adhered to the surface of the wafer W can be removed. Furthermore, since the pressure difference between the processing container and the substrate transport chamber 300 is reduced by the pressure adjustment process, it is possible to suppress particles from adhering onto the wafer W due to a gas flow when the gate valve 115 is opened.

### [Comparison of Numbers of Particles]

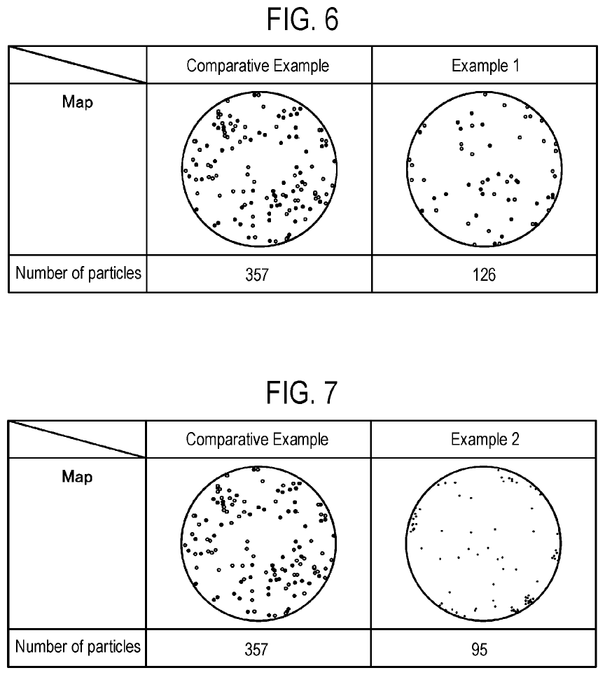

Next, a comparison of the numbers of particles on wafers W depending on the presence and absence of the pressure change process and the pressure adjustment process will be described with reference to FIGS. 6 to 8. In FIGS. 6 to 8, a case where only the film forming process was performed is taken as Comparative Example, and a case where the film forming process and the pressure change process were carried out is taken as Example 1. In addition, a case where the film forming process and the pressure adjustment process were performed is taken as Example 2, and a case where the film forming process, the pressure change process, and the pressure adjustment process were performed is taken as Example 3. In FIGS. 6 to 8, an evaluation method capable of detecting particles of 32 nm or more is used.

FIG. 6 is a view showing an example of a comparison of the numbers of particles in Comparative Example and Example 1. As illustrated in FIG. 6, in Comparative Example, 357 particles were detected with the distribution illustrated in the Map column. On the other hand, in Example 1, 126 particles were detected with the distribution illustrated in the Map column. Thus, in Example 1, it was possible to reduce the number of particles to half or less of that of Comparative Example.

FIG. 7 is a view showing an example of a comparison of the numbers of particles in Comparative Example and Example 2. As illustrated in FIG. 7, in Comparative Example, 357 particles were detected with the distribution illustrated in the Map column. On the other hand, in Example 2, 95 particles were detected with the distribution illustrated in the Map column. Thus, in Example 2, it was possible to reduce the number of particles to ⅓ or less of that of Comparative Example.

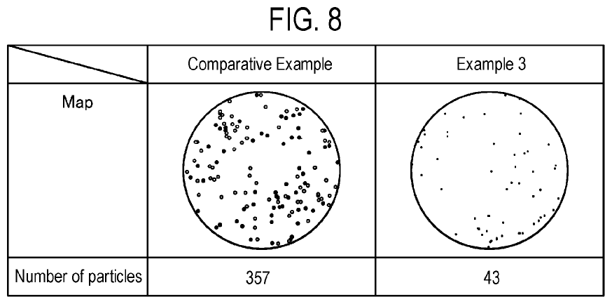

FIG. 8 is a view illustrating an example of a comparison of the numbers of particles in Comparative Example and Example 3. As illustrated in FIG. 8, in Comparative Example, 357 particles were detected with the distribution illustrated in the Map column. On the other hand, in Example 3, 43 particles were detected with the distribution illustrated in the Map column. Thus, in Example 3, it was possible to reduce the number of particles to 1/7 or less of that of Comparative Example. From Examples 1 to 3, it can be seen that although particles can be reduced even if each of the pressure change process and the pressure adjustment process are performed independently after the film forming process, particles can be further reduced by combining the pressure change process and the pressure adjustment process.

### Second Embodiment

In the above-described first embodiment, the substrate processing apparatus 100 having a plurality of plasma sources (the microwave radiation mechanisms 143) is used, but a substrate processing apparatus having a single-phase plasma source may be used. An embodiment in this case will be described as a second embodiment. Some of the components of the substrate processing apparatus and the film forming method in the second embodiment are the same as those in the above-described first embodiment, so redundant descriptions of the components and operations will be omitted.

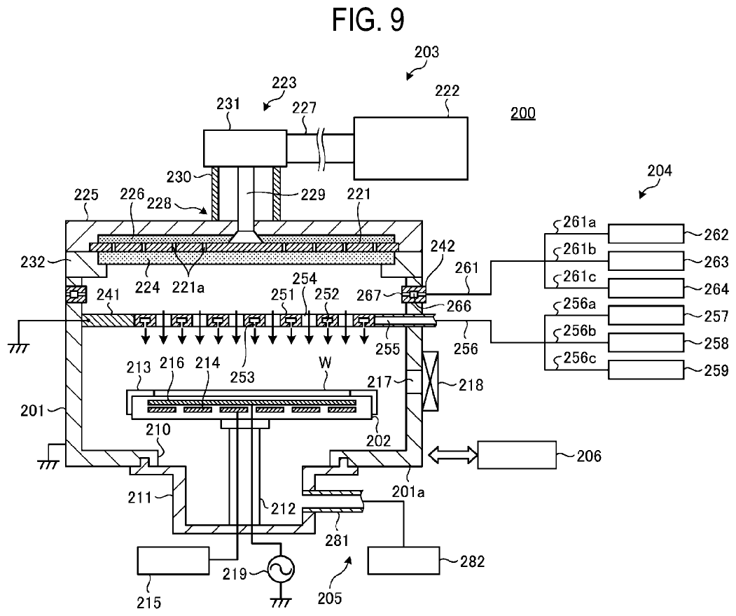

FIG. 9 is a view illustrating an example of the substrate processing apparatus according to the second embodiment of the present disclosure. The substrate processing apparatus 200 illustrated in FIG. 9 includes a processing container 201, a stage 202, a microwave introduction mechanism 203, a gas supplier 204, an exhauster 205, and a controller 206. The processing container 201 has a substantially cylindrical shape and accommodates a wafer W therein. The wafer W is placed on the stage 202. The microwave introduction mechanism 203 generates microwaves for generating plasma in the processing container 201 and introduces the microwaves into the processing container 201. The gas supplier 204 supplies gas into the processing container 201. The gas exhauster 205 evacuates the interior of the processing container 201. The controller 206 controls the operation of each part of the substrate processing apparatus 200.

A circular opening 210 is formed in a substantially central portion of the bottom wall 201a of the processing container 201, and the bottom wall 201a is provided with an exhaust chamber 211 that communicates with the opening 210 and protrudes downward. The side wall of the processing container 201 is provided with a carry-in/out port 217 for carrying-in/out a wafer W and a gate valve 218 configured to open/close the carry-in/out port 217.

The stage 202 has a disk shape and is made of ceramic such as AlN. The stage 202 is supported by a cylindrical support member 212 made of ceramic such as AlN and extending upward from the center of the bottom portion of the exhaust chamber 211. A guide ring 213 configured to guide a wafer W is provided on the outer edge of the stage 202. In addition, a heater 214 and an electrode 216 are embedded in the stage 202, similarly to the stage 102 of the substrate processing apparatus 100, and are connected to a heater power supply 215 and a radio frequency bias power supply 219, respectively.

The microwave introduction mechanism 203 includes a planar slot antenna 221 provided to face the opening in the upper portion of the processing container 201 and provided with a large number of slots 221a, a microwave generator 222 configured to generate microwaves, and a microwave transmission mechanism 223 configured to guide the microwaves from the microwave generator 222 to the planar slot antenna 221. Below the planar slot antenna 221, a microwave transmitting plate 224 made of a dielectric material is provided to be supported by an upper plate 232 provided in a ring shape in the upper portion of the processing container 201, and a shield member 225 having a water-cooled structure is provided above the planar slot antenna 221. In addition, a slow-wave material 226 is provided between the shield member 225 and the planar slot antenna 221.

The planar slot antenna 221 is made of, for example, a copper plate or an aluminum plate having a silver or gold-plated surface, and has a configuration in which a plurality of slots 221a for radiating microwaves is formed through the plate in a predetermined pattern. The pattern of the slots 221a is appropriately set such that the microwaves are evenly radiated. An example of a suitable pattern includes a radial line slot in which a plurality of pairs of slots 221a are concentrically arranged, and the two slots 221a in each pair are arranged in a T shape. The lengths and the arrangement intervals of the slots 221a are appropriately determined depending on the effective wavelength Xg of microwaves. The slots 221a may have other shapes such as a circular shape and an arc shape. The arrangement form of the slots 221a is not particularly limited, and the slots 221a may be arranged, for example, in a spiral shape or a radial shape, in addition to the concentric shape. The pattern of the slots 221a is appropriately set to have a microwave radiation characteristic that obtains a desired plasma density distribution.

The slow-wave material 226 is made of a dielectric material having a dielectric constant greater than that of a vacuum, for example, quartz, ceramic (Al₂O₃), or a resin such as polytetrafluoroethylene or polyimide. The slow-wave material 226 functions to make the wavelength of the microwaves shorter than that in a vacuum, thereby reducing the size of the planar slot antenna 221. The microwave transmitting plate 224 is also made of the same dielectric material.

The thicknesses of the microwave transmitting plate 224 and the slow-wave material 226 are adjusted such that an equivalent circuit formed by the slow-wave material 226, the planar slot antenna 221, the microwave transmitting plate 224, and the plasma satisfies resonance conditions. By adjusting the thickness of the slow-wave material 226, the phase of the microwaves can be adjusted, and by adjusting the thickness of the planar slot antenna such that the joint portion of the planar slot antenna 221 becomes an “antinode” of a standing wave, the reflection of microwaves is minimized and the radiant energy of microwaves is maximized. In addition, when the slow-wave material 226 and the microwave transmitting plate 224 are made of the same material, it is possible to prevent an interface reflection of microwaves.

The microwave generator 222 includes a microwave oscillator. The microwave oscillator may be a magnetron oscillator or a solid-state oscillator. The frequency of microwaves oscillated from the microwave oscillator may be in the range of 300 MHz to 10 GHz. For example, by using the magnetron as the microwave oscillator, it is possible to oscillate microwaves having a frequency of 2.45 GHz.

The microwave transmission mechanism 223 includes a waveguide 227 extending in the horizontal direction for guiding microwaves from the microwave generator 222, a coaxial waveguide 228 including an inner conductor 229 extending upward from the center of the planar slot antenna 221 and an outer conductor 230 outside the inner conductor 229, and a mode conversion mechanism 231 provided between the waveguide 227 and the coaxial waveguide 228. The microwaves generated by the microwave generator 222 propagate through the waveguide 227 at a TE mode, and the vibration mode of the microwaves is converted from the TE mode to a TEM mode by the mode conversion mechanism 231. The converted microwaves are guided to the slow-wave material 226 via the coaxial waveguide 228 and are radiated from the slow-wave material 226 into the processing container 201 through the slots 221a in the planar slot antenna 221 and the microwave transmitting plate 224. A tuner (not illustrated) is provided in the middle of the waveguide 227 to match the impedance of a load (plasma) in the processing container 201 with the characteristic impedance of the power supply of the microwave generator 222.

The gas supplier 204 includes a shower plate 241 horizontally provided above the stage 202 in the processing container 201 to partition the upper and lower portions of the interior of the processing container 201, and a shower ring 242 provided above the shower plate 241 in a ring shape along the inner wall of the processing container 201.

The shower plate 241 includes grid-shaped gas flow members 251, gas flow paths 252 provided in a grid shape inside the gas flow members 251, respectively, and a large number of gas ejection holes 253 extending downward from the gas flow path 252, and through holes 254 are provided between the grid-shaped gas flow members 251. A gas supply path 255 reaching the outer wall of the processing container 201 extends to the gas flow paths 252 in the shower plate 241, and a gas supply pipe 256 is connected to the gas supply path 255. The gas supply pipe 256 branches into three branch pipes 256a, 256b, and 256c. These branch pipes 256a, 256b, and 256c are respectively connected to a H₂ gas source 257 configured to supply H₂ gas as a reducing gas, a C₂H₄ gas source 258 configured to supply ethylene (C₂H₄) gas as a carbon-containing gas which is a film forming raw-material gas, and a N₂ gas source 259 configured to supply N₂ gas used as a purge gas or the like. Although not illustrated, each of the branch pipes 256a, 256b, and 256c is provided with a mass flow controller configured to control a flow rate and valves before and after the mass flow controller.

The shower ring 242 includes a ring-shaped gas flow path 266 provided therein and a large number of gas ejection holes 267 connected to the gas flow path 266 and opening to the inside of the gas flow path 266, and a gas supply pipe 261 is connected to the gas flow path 266. The gas supply pipe 261 branches into three branch pipes 261a, 261b, and 261c. These branch pipes 261a, 261b, and 261c are respectively connected to an Ar gas source 262 configured to supply Ar gas as a rare gas which is a plasma generating gas, an O₂ gas source 263 configured to supply O₂ gas as an oxidizing gas which is a cleaning gas, and a N₂ gas source 264 configured to supplying N₂ gas used as a purge gas or the like. Although not illustrated, each of the branch pipes 261a, 261b, and 261c is provided with a mass flow controller configured to control a flow rate and valves before and after the mass flow controller.

The exhauster 205 includes the exhaust chamber 211, an exhaust pipe 281 provided on the side surface of the exhaust chamber 211, and an exhauster 282 connected to the exhaust pipe 281 and including a vacuum pump, a pressure control valve, and the like.

The controller 206 is typically configured with a computer, and controls each part of the substrate processing apparatus 200. The controller 206 includes a storage that stores a process sequence of the substrate processing apparatus 200 and process recipes as control parameters, an input part, and a display, and is able to perform predetermined control according to a selected process recipe.

For example, the controller 206 controls each part of the substrate processing apparatus 200 to perform the film forming method of the first embodiment described above. As a detailed example, the controller 206 executes a carry-in process of carrying a substrate (a wafer W) into the processing container 201. The controller 206 executes a film forming process of forming a first carbon film on the substrate with plasma of a first mixture gas containing a carbon-containing gas while the interior of the processing container 201 is maintained at a first pressure. The controller 206 executes a pressure change process of changing the pressure in the processing container 201 to a second pressure higher than the first pressure. As a result, similarly to the film forming method of the first embodiment, the generation of particles can be reduced in the substrate processing apparatus 200 of the second embodiment.

As described above, according to each embodiment, the substrate processing apparatuses 100 and 200 respectively include processing containers 101 and 201 capable of accommodating a substrate (a wafer W) and a controller 106 and 206, respectively. The controller executes a carry-in process of carrying a substrate into the processing chamber, a first process of forming a first carbon film (the graphene film 118) on the substrate with plasma of a first mixture gas containing a carbon-containing gas while the interior of the processing chamber is maintained at a first pressure (film forming process), and a second process of changing the pressure in the processing container to a second pressure higher than the first pressure (pressure change process). As a result, the generation of particles can be reduced, and the particles adhered to the surface of the wafer W can be removed.

Further, according to each embodiment, in the second process, the pressure in the processing container is changed to the second pressure while the plasma of the first mixture gas is maintained, and a second carbon film (an amorphous carbon film 125) is formed in the processing container. As a result, peeling of a plate-shape amorphous carbon film formed on the inner wall of the processing container can be suppressed.

According to each embodiment, the first carbon film is graphene, and the second carbon film is amorphous carbon. As a result, peeling of a plate-shape amorphous carbon film formed on the inner wall of the processing container can be suppressed.

Further, according to each embodiment, in the second process, by stopping the supply of the carbon-containing gas in the state in which the plasma of the first mixture gas is maintained, the first mixture gas is switched to a second mixture gas which does not contain the carbon-containing gas and the pressure in the processing container is changed to a second pressure while the plasma of the second mixture gas is maintained. As a result, the generation of particles can be reduced, and the particles adhered to the surface of the wafer W can be removed.

In addition, according to each embodiment, in the second process, a hydrogen-containing gas is supplied into the processing container to activate the plasma, so that the substrate is processed with the activated active species. As a result, the particles adhered to the surface of the wafer W can be removed more quickly.

In addition, according to each embodiment, the first pressure is 50 mTorr to 200 mTorr, and the second pressure is 300 mTorr to 2 Torr. As a result, the generation of particles can be reduced, and the particles adhered to the surface of the wafer W can be removed.

In addition, according to each embodiment, the plasma is microwave plasma generated by microwave power. As a result, the electron energy of the plasma on the wafer W is controlled to be low, and the graphene film can be formed without damaging the surface of the graphene film 118 and the wafer W.

In addition, each embodiment further includes: a third process of, after the second process, stopping the plasma and changing the pressure in the processing container to a third pressure having a pressure difference from a pressure in the substrate transport chamber 300 to which the substrate is transported that is equal to or less than a predetermined value (pressure adjustment process); and a carry-out process of carrying out the substrate in the processing container into the substrate transport chamber 300 while the pressure in the processing container is maintained at the third pressure. As a result, when the gate valve 115 is opened, particles can be prevented from adhering to the wafer W due to turbulence of gas flow.

In addition, according to each embodiment, the predetermined value is 30 mTorr, and the third pressure is lower than the pressure in the substrate transport chamber 300. As a result, the outflow of particles into the substrate transport chamber 300 can be suppressed.

It shall be understood that each embodiment disclosed herein is exemplary in all respects and not restrictive. Each of the above-described embodiments may be omitted, replaced, or modified in various forms without departing from the scope and spirit of the appended claims.

In each of the above-described embodiments, a case in which a graphene film is formed on a wafer W has been described, but the present disclosure is not limited thereto. For example, each of the embodiments is also applicable to a case where an amorphous carbon film, a diamond-like carbon film, or a carbon nanotube film is formed on the wafer W.

In addition, in each of the above-described embodiments, for example, a case in which a graphene film is formed on a wafer W, which is a silicon substrate, has been described, but the present disclosure is not limited thereto. For example, as long as a polysilicon film is formed as a base film on the wafer W, the present disclosure can also be applied to a case where a graphene film is formed on the polysilicon film. The base film can also be applied not only in a case where a graphene film or the like is formed on a polysilicon film, but also in a case where a graphene film or the like is formed on a metal film of Cu, Ni, Co, W, Ti, or the like. Furthermore, the base film can also be applied in a case where a graphene film or the like is formed on a metal oxide film or a metal nitride film.

In addition, in each of the above-described embodiments, the cleaning process is performed each time, but the present disclosure is not limited to this. For example, for a plurality of wafers W in one lot, the film forming process, the pressure change process, and the pressure adjustment process are performed for each wafer W, and the cleaning process may be performed at a time point when processes for a predetermined number of wafers (e.g., one lot) is completed.

In each of the above-described embodiments, substrate processing apparatuses 100 and 200 that perform a process such as film formation or light etching on a wafer W by using microwave plasma as a plasma source have been described as an example, but the disclosed technique is not limited thereto. The plasma source is not limited to the microwave plasma as long as the apparatus uses plasma to process a wafer W, and any plasma source, such as capacitively-coupled plasma, inductively-coupled plasma, or magnetron plasma, may be used.

### EXPLANATION OF REFERENCE NUMERALS

100, 200: substrate processing apparatus, 101, 201: processing container, 102, 202: stage, 106, 206: controller, 118: graphene film, 125: amorphous carbon film, W: wafer

1-10. (canceled)

11. A substrate processing method of processing a substrate, the substrate processing method comprising:
a carry-in process of carrying the substrate into a processing container;
a first process of forming a first carbon film on the substrate with plasma of a first mixture gas containing a carbon-containing gas in a state in which interior of the processing container is maintained at a first pressure; and
a second process of changing a pressure in the processing container to a second pressure higher than the first pressure.

12. The substrate processing method of claim 11, wherein, in the second process, while the plasma of the first mixture gas is maintained, the pressure in the processing container is changed to the second pressure and a second carbon film is formed in the processing container.

13. The substrate processing method of claim 12, wherein the first carbon film is graphene, and the second carbon film is amorphous carbon.

14. The substrate processing method of claim 13, wherein, in the second process, a hydrogen-containing gas is supplied into the processing container to activate the plasma, and the substrate is processed with activated active species.

15. The substrate processing method of claim 14, wherein the first pressure is 50 mTorr to 200 mTorr, and the second pressure is 300 mTorr to 2 Torr.

16. The substrate processing method of claim 15, wherein the plasma is microwave plasma generated by microwave power.

17. The substrate processing method of claim 16, further comprising:
a third process of, after the second process, stopping the plasma and changing the pressure in the processing container to a third pressure having a pressure difference from a pressure in a substrate transport chamber to which the substrate is transported that is equal to or less than a predetermined value; and
a carry-out process of carrying out the substrate in the processing container into the substrate transport chamber while the pressure in the processing container is maintained at the third pressure.

18. The substrate processing method of claim 17, wherein the predetermined value is 30 mTorr, and
wherein the third pressure is lower than the pressure in the substrate transport chamber.

19. The substrate processing method of claim 11, wherein, in the second process, by stopping supply of the carbon-containing gas in a state in which the plasma of the first mixture gas is maintained, the first mixture gas is switched to a second mixture gas that does not contain the carbon-containing gas, and the pressure in the processing container is changed to the second pressure in a state in which the plasma of the second mixture gas is maintained.

20. The substrate processing method of claim 11, wherein, in the second process, a hydrogen-containing gas is supplied into the processing container to activate the plasma, and the substrate is processed with activated active species.

21. The substrate processing method of claim 11, wherein the first pressure is 50 mTorr to 200 mTorr, and the second pressure is 300 mTorr to 2 Torr.

22. The substrate processing method of claim 11, wherein the plasma is microwave plasma generated by microwave power.

23. The substrate processing method of claim 11, further comprising:
a third process of, after the second process, stopping the plasma and changing the pressure in the processing container to a third pressure having a pressure difference from a pressure in a substrate transport chamber to which the substrate is transported that is equal to or less than a predetermined value; and
a carry-out process of carrying out the substrate in the processing container into the substrate transport chamber while the pressure in the processing container is maintained at the third pressure.

24. A substrate processing apparatus comprising:
a processing container configured to accommodate a substrate; and
a controller,
wherein the controller is configured to:
control the substrate processing apparatus such that the substrate is carried into the processing container;
control the substrate processing apparatus such that a first carbon film is formed on the substrate with plasma of a first mixture gas containing a carbon-containing gas in a state in which a pressure in the processing container is maintained at a first pressure; and
control the substrate processing apparatus to change the pressure in the processing container to a second pressure higher than the first pressure.
